(19) United States
(12) Patent Application Publication
(10) Pub. No.: US 2013/0248882 A1
(43) Pub. Date: Sep. 26, 2013

(54) SEMICONDUCTOR DEVICE

(71) Applicant: KABUSHIKI KAISHA TOSHIBA, Tokyo (JP)

(72) Inventors: Tsuneo OGURA, Kanagawa (JP); Tomoko MATSUDAI, Tokyo (JP); Yuichi OSHINO, Tokyo (JP); Hideaki NINOMIYA, Hyogo (JP)

(73) Assignee: KABUSHIKI KAISHA TOSHIBA, Tokyo (JP)

(21) Appl. No.: 13/784,744

(22) Filed: Mar. 4, 2013

(30) Foreign Application Priority Data
Mar. 26, 2012 (JP) 2012-069800

(51) Int. Cl. H01L 29/739; H01L 29/66

(52) U.S. Cl. CPC H01L 29/7395; H01L 29/66348
USPC 257/77; 257/140; 257/76; 438/138

(57) ABSTRACT

In a semiconductor device, transistor cells and diode cells are formed on a single semiconductor substrate of a first conductivity type. A first semiconductor layer of a second conductivity type is formed in a transistor cell region and at a lower side of the substrate. A second semiconductor layer of the first conductivity type is formed in a region adjacent to the transistor cell region and at the lower side of the substrate. Gate electrodes are formed at an upper side of the substrate. A third semiconductor layer of the second conductivity type and a fourth semiconductor layer of the first conductivity type are formed between the gate electrodes. A fifth semiconductor layer of the first conductivity type is formed above the first semiconductor layer in the transistor cell region. A first and a second electrode are formed on both sides of the substrate.

### CROSS-REFERENCE TO RELATED APPLICATION

This application is based upon and claims the benefit of priority from Japanese Patent Application No. 2012-069800, filed Mar. 26, 2012, the entire contents of which are incorporated herein by reference.

### FIELD

Embodiments described herein relate to a semiconductor device.

### BACKGROUND

An inverter circuit includes an insulated gate-type bipolar transistor (hereinafter referred to as an IGBT) as a switching device and a diode for reflux that is connected in an inversely parallel orientation with the IGBT. With the placement of the IGBT and the diode on one chip, the inverter circuit can be made small in scale. For example, a structure in which part of the p collector layer of the IGBT is replaced with an n-type layer and used as a cathode layer in the diode is proposed.

However, if the IGBT and the diode are formed on one chip then the area of the IGBT is reduced, which reduces the amount of electric current that may be applied thereto. If the area of the IGBT is increased to receive a larger current, then the diode region is reduced, which reduces the amount of electric current that may be applied to the diode. Therefore, if the IGBT and the diode are formed on one chip, then the characteristics of at least one of the IGBT and the diode are compromised.

### DESCRIPTION OF THE DRAWINGS

FIG. 1 is a cross section showing the semiconductor device of an embodiment.

FIG. 2 is a graph showing an example of the voltage-current characteristics of a diode.

FIG. 3 is a process cross section for explaining the method of manufacturing the semiconductor device of the embodiment.

FIG. 4 is a process cross section subsequent to FIG. 3.

FIG. 5 is a process cross section subsequent to FIG. 4.

FIG. 6 is a process cross section subsequent to FIG. 5.

FIG. 7 is a process cross section subsequent to FIG. 6.

FIG. 8 is a process cross section subsequent to FIG. 7.

FIG. 9 is a process cross section subsequent to FIG. 8.

FIG. 10 is a process cross section subsequent to FIG. 9.

FIG. 11 is a process cross section subsequent to FIG. 10.

FIG. 12 is a cross section showing a semiconductor device in a modified example.

FIG. 13 shows an example of the arrangement of a collector region of an IGBT and a cathode region of a diode.

FIG. 14 shows an example of the arrangement of a collector region of an IGBT and a cathode region of a diode.

FIG. 15 is a cross section showing a semiconductor device in a modified example.

FIG. 16 is a cross section showing a semiconductor device in a modified example.

### DETAILED DESCRIPTION

Embodiments provide a semiconductor device with good characteristics for an insulated gate-type bipolar transistor (IGBT) and a diode formed as a single chip.

A general description according to one embodiment of the present disclosure will be explained with reference to the figures.

According to this embodiment, in a semiconductor device, transistor cells and diode cells are formed on a first conductivity type semiconductor substrate. This semiconductor device is provided with a first semiconductor layer of a second conductivity type that is formed in a transistor cell region and at a lower side of the semiconductor substrate. The following layers and components are added: a second semiconductor layer of the first conductivity type that is formed in a region adjacent to the IGBT cell region and at the lower side of the semiconductor substrate; gate electrodes that are formed with a prescribed spacing at an upper side of the semiconductor substrate; a third semiconductor layer of the second conductivity type that is formed between the gate electrodes; a fourth semiconductor layer of the first conductivity-type that is formed between the gate electrodes; a fifth semiconductor layer of the first conductivity type that is formed above the first semiconductor layer and in the transistor cell region; a first electrode that is formed on the third semiconductor layer and the fourth semiconductor layer; and a second electrode that is formed on the lower surface of the semiconductor substrate.

FIG. 1 is a cross section showing a semiconductor device of the embodiment of the disclosed invention. For example, the semiconductor device 1 is used in an inverter circuit that has an IGBT (insulated gate-type bipolar transistor) and a diode that is connected in an inversely parallel orientation with the IGBT. As shown in FIG. 1, in the semiconductor device 1 an IGBT cell region A1 and a cell region A2 for the IGBT and diode adjacent to the IGBT cell region A1 are formed on an n conductivity type semiconductor substrate (n-base layer) 15.

On an upper side of the semiconductor substrate 15, an n-type semiconductor layer 11 and a p-type semiconductor layer 12 are formed. The n-type semiconductor layer 11 acts as an n emitter region of the IGBT cells. In addition, the p-type semiconductor layer 12 acts as the channel formation region of the IGBT cells, p base region, and anode region of the diode cells.

In addition, a section of the upper side of the semiconductor substrate 15 is etched with a prescribed spacing to form gate trenches that penetrate through the n-type semiconductor layer 11 and the p-type semiconductor layer 12, and gate electrodes 13 are formed in the gate trenches. Thus, the n-type semiconductor layer 11 and the p-type semiconductor layer 12 are formed between the gate trenches (gate electrodes 13). The gate electrodes 13 face gate insulating films 14 that are formed at the side walls of the gate trenches. Thus, the gate electrode 13 is insulated from the n-type semiconductor layer 11 and the p-type semiconductor layer 12 by the gate insulating film 14. Here, the gate electrodes 13 of the cell region A2 for the IGBT and the diode are also similarly connected by wirings and operated by the IGBT as well as the diode.

In the IGBT cell region A1, an n-type barrier layer (n-type semiconductor layer) 20 is formed directly under the p-type semiconductor layer 12. The n-type barrier layer 20 is not formed in the cell region A2 for the IGBT and the diode.

In the IGBT cell region A1 of a lower surface layer area of the semiconductor substrate 15, a p-type semiconductor layer 17 is formed as a contact region, and in the cell region A2 for the IGBT and the diode, an n-type semiconductor layer 18 is formed as a cathode region. In addition, an n buffer layer 16 is formed on the p-type semiconductor layer 17 and the n-type semiconductor layer 18.

On the gate electrodes and the gate insulating film 14, an emitter electrode 10 is formed, and a collector electrode 19 is formed on the p-type semiconductor layer 17 and the n-type semiconductor layer 18.

In the IGBT cell region A1, a channel layer is created in the p-type semiconductor layer 12 by applying a voltage to the gate electrode 13, which controls the conduction between the n-type semiconductor layer (emitter) 11 and the p-type semiconductor layer (collector) 17. If a voltage is applied to the gate electrode 13 and the potential of the emitter electrode 10 is lower than that of the collector electrode 19, then an electric current flows from the n-type semiconductor layer 11 to the n-type semiconductor layer 18. Next, the pn that is formed by the p-type semiconductor layer 17 and the n-type semiconductor layer 18 is biased forward, a hole current flows from the p-type semiconductor layer 17 to the p-type semiconductor layer 12, which operates the IGBT.

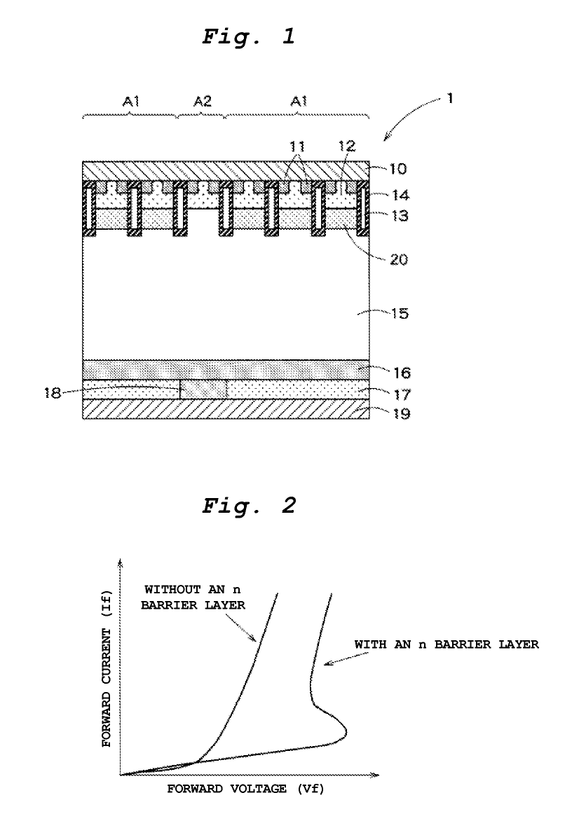

In this embodiment, the n-type barrier layer 20 is formed in the IGBT cell region A1 to lower the on-state voltage of the IGBT. In addition, because the IGBT is operated even in the cell region A2 for the IGBT and the diode, the whole surface is subjected to the IGBT operation and has no influence on the existence of the diode region. Moreover, because the n-type barrier layer 20 is not formed in the cell region A2 for the IGBT and the diode, the characteristics of the diode can be improved compared with the case in which the n-type barrier layer 20 is formed in the cell region A2 for the IGBT and the diode. FIG. 2 shows an example of the voltage-current (Vf-If) relationship when a diode in which the n-type barrier layer 20 is formed and a diode in which the n-type barrier layer 20 is not formed are operated forward. In the diode in which the n-type barrier layer 20 is not formed, a higher forward operational current can be obtained at the same forward operational voltage compared with the diode in which the n-type barrier layer 20 is formed. Thus, at the same forward operational current, the forward operational voltage can be lowered. Therefore, in the diode in which the n-type barrier layer 20 is not formed, its response is improved compared with the diode in which the n-type barrier layer 20 is formed.

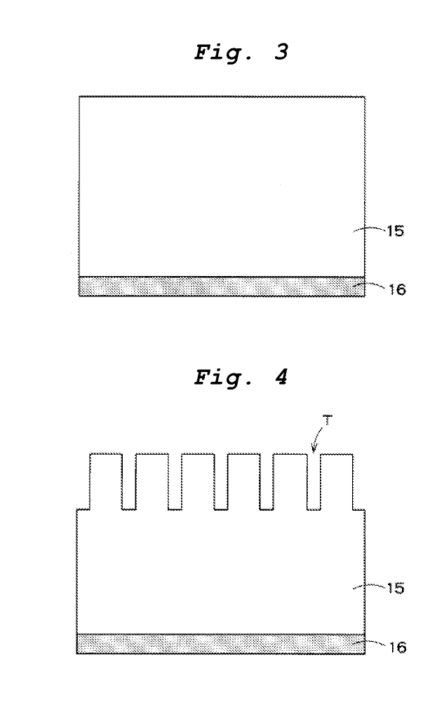

Next, the method for manufacturing the semiconductor device of this embodiment will be explained with references to FIG. 3 through FIG. 11.

First, as shown in FIG. 3, the n conductivity-type semiconductor substrate 15 that has the n buffer layer 16 on the lower surface is prepared.

Next, as shown in FIG. 4, trenches (grooves) T are formed with a prescribed spacing on the upper surface of the semiconductor substrate 15 by RIE (reactive ion etching).

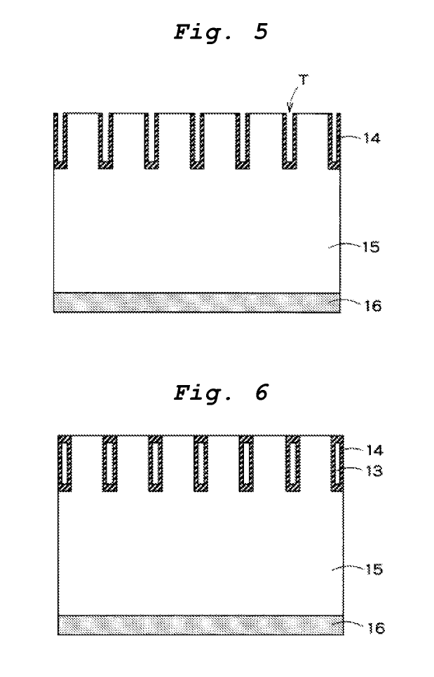

Next, as shown in FIG. 5, silicon oxide films are deposited on the side walls and at the bottom of the trenches T by CVD (chemical vapor deposition) or ALD (atomic layer deposition) to form the gate insulating films 14.

Next, as shown in FIG. 6, polysilicon is embedded up to a prescribed depth into the trenches T to form the gate electrodes 13. Silicon oxide films are then embedded into the upper part of the trenches T to protect the gate electrodes 13.

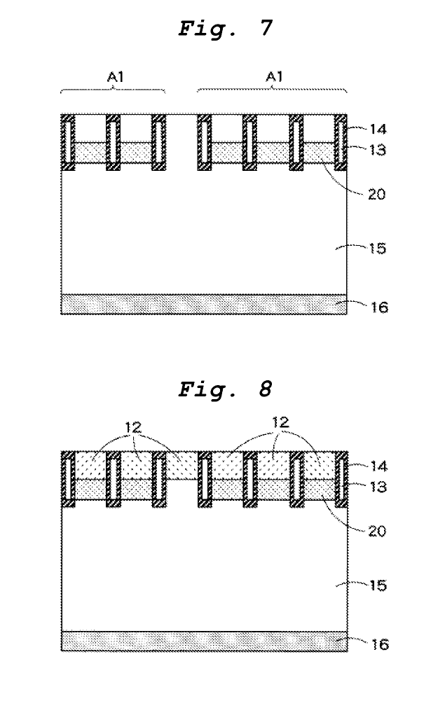

Next, as shown in FIG. 7, using a mask (not shown in the figure), n-type impurities are implanted and diffused only into the IGBT cell region A1 from the upper side of the semiconductor substrate 15 by a PEP process to form the n-type barrier layer 20.

Next, as shown in FIG. 8, p-type impurities are implanted and diffused into the entire upper surface of the semiconductor substrate 15 to form the p-type semiconductor layer 12.

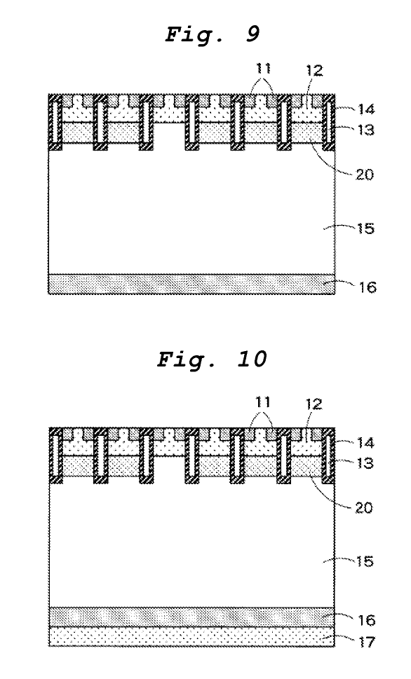

Next, as shown in FIG. 9, using a mask (not shown in the figure), n-type impurities are implanted and diffused into a region corresponding to the n emitter region of the IGBT cells from the upper side of the semiconductor substrate 15 to form the n-type semiconductor layer 11.

Next, as shown in FIG. 10, p-type impurities are implanted and diffused from the lower surface of the semiconductor substrate 15 to form the p-type semiconductor layer 17.

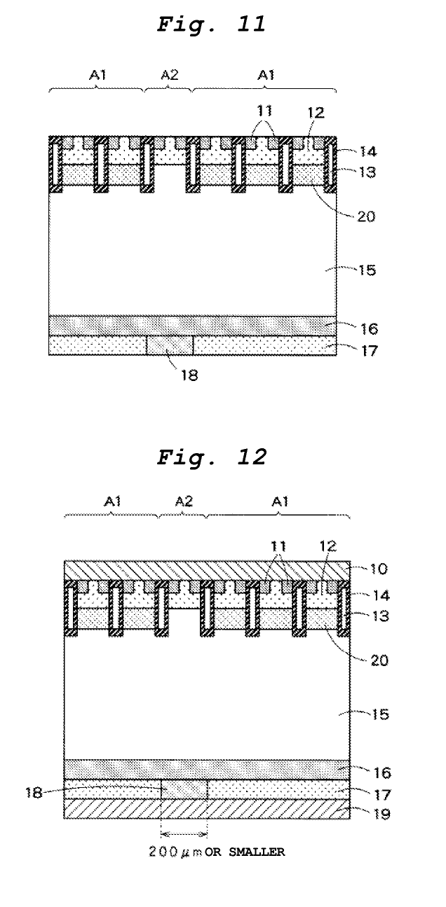

Next, as shown in FIG. 11, through the PEP process and using a mask (not shown in the figure), n-type impurities are implanted and diffused only into the cell region A2 for the IGBT and the diode from the lower side of the substrate 15 to form the n-type semiconductor 18.

Finally, with the formation of an electrode layer including the emitter electrode 10 and the collector electrode 19 on the upper surface and the lower surface of the semiconductor substrate 15, one is able to obtain the semiconductor device as shown in FIG. 1.

As mentioned above, according to this embodiment the on-state voltage of the IGBT can be lowered by forming the n-type barrier layer 20 in the IGBT cell region A1. In addition, the cell region A2 for the IGBT and the diode can be utilized as the IGBT, and the n-type barrier layer 20 is not formed in the cell region A2 for the IGBT and the diode. Thus, the characteristics can be improved compared with the diode in which the n-type barrier layer 20 is formed. Therefore, in the semiconductor device 1 of this embodiment the characteristics of the IGBT and the diode formed as one chip are good.

In the embodiment, it is desirable to narrow the width of the n-type semiconductor layer 18 as a cathode region of the diode so that a carrier extends along the entire surface of the semiconductor substrate (n base layer) 15 in a conductive state with the IGBT. Usually, the carrier extends approximately a diffusion length in the horizontal direction. If the diffusion coefficient is Dₙ and the lifetime is τₙ, the diffusion length Lₙ of electrons is expressed by the following mathematical expression:

Lₙ=\sqrt{Dₙτₙ} (Expression 1)

where when Dₙ=36.4 cm²/sec, τₙ=10×10⁻⁶ sec, and Lₙ=190 μm. Therefore, if the width of the n-type semiconductor layer 18 is approximately 200 μm or smaller, the on-state voltage of the IGBT can be prevented from rising even in an arrangement in which the diode is built with the IGBT.

Here, as shown in FIG. 12, when the width of the n-type semiconductor layer 18 is 200 μm or smaller, the n-type barrier layer 20 of the cell region A2 for the IGBT and the diode may also be omitted. The width of the n-type semiconductor layer 18 equals to the width between the two adjacent p-type semiconductor layers 17, as shown in FIG. 12. In the arrangement shown in FIG. 12, the on-state voltage of the IGBT is increased by as much as the omitted portion of the n-type barrier layer 20 compared with the arrangement shown in FIG. 1. However, if the width of the n-type semiconductor layer 18 is set to 200 μm or smaller, then the rise of the on-state voltage of the IGBT can be suppressed, because the carrier extends to the entire surface of the semiconductor substrate (n base layer) 15 in a conductive state with the IGBT. In addition, the manufacturing costs can be reduced by as much as the omitted portion of the n-type barrier layer 20.

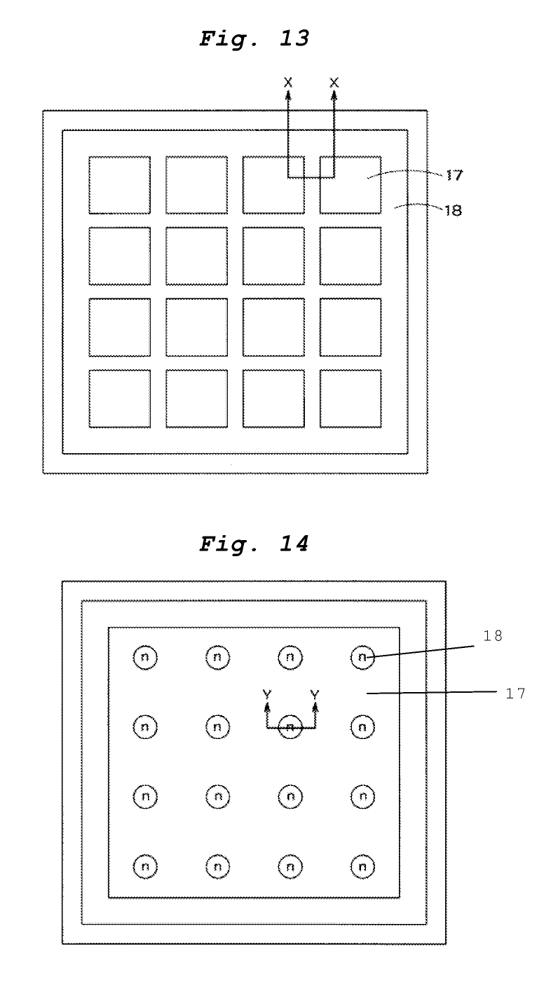

FIG. 13 shows an example of the arrangement of the p-type semiconductor layers 17 as collector regions of the IGBT and the n-type semiconductor layer 18 as cathode regions of the diode. The n-type semiconductor layer 18 is formed in a grid shape, and each p-type semiconductor layer 17 has a rectangular shape enclosed with the grid-shaped n-type semiconductor layer 18. Here, the vertical cross section along line X-X of FIG. 13 corresponds to FIG. 1.

Moreover, as shown in FIG. 14, a structure in which the n-type semiconductor layer 18 is arranged in a water drop shape and the p-type semiconductor layer 17 encloses the n-type semiconductor layer 18 may also be used. The vertical cross section along line Y-Y of FIG. 14 corresponds to FIG. 1. The width of the n-type semiconductor layer 18 equals to the diameter of the circle of the n-type semiconductor layer 18, if the n-type semiconductor layer 18 is arranged in the shape of a water drop, as shown in FIG. 14.

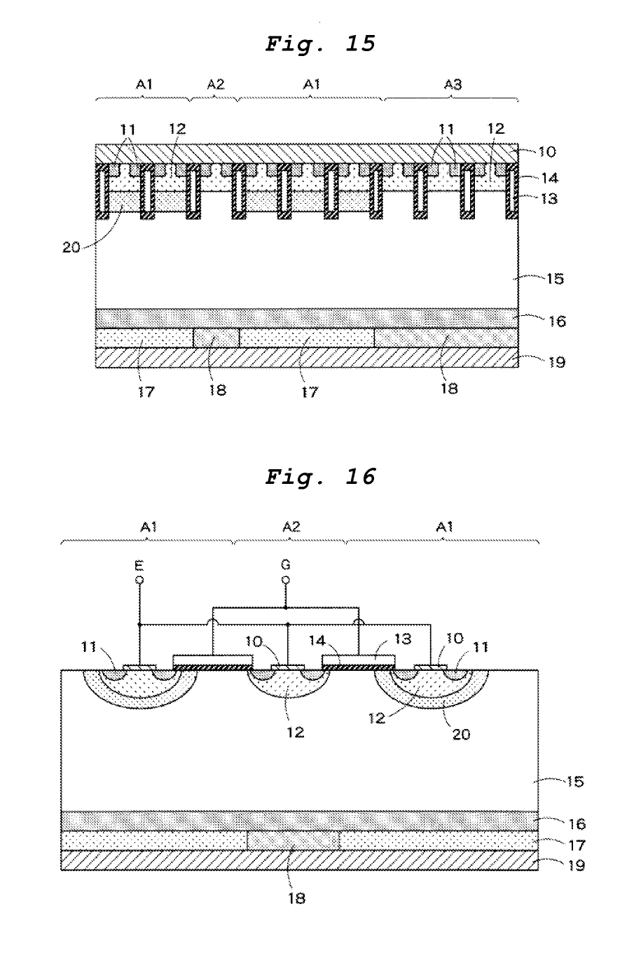

In the semiconductor device of the embodiment, as shown in FIG. 1, the cell region A2 with a narrow width for the IGBT and the diode has been formed between the IGBT cell regions A1 with a wide width; however, as shown in FIG. 15, a single diode region A3 may additionally be formed. For example, the single diode region A3 has an arrangement similar to the arrangement of the cell region A2 for the IGBT and the diode.

If the width of the cell region A2 for the IGBT and the diode is narrowed, the on-state voltage of the diode is raised. However, as shown in FIG. 15, with the single diode region A3, the area of the diode is sufficiently secured, and thus the on-state characteristics of the diode can be improved. In addition, in the single diode region A3, the design at the anode is possible regardless of the IGBT.

Here, in the embodiment, only one region enclosed by the trench has been shown in the cell region A2 for the IGBT and diode; however, even when multiple regions are enclosed by the trench, the arrangement of the embodiment can be applied.

In the semiconductor device of the embodiment, the gate electrodes 13 have a trench structure; however, as shown in FIG. 16, the gate electrodes 13 may also have a planar structure. In FIG. 16, the same symbols are given to the areas that correspond to the areas of the embodiment shown in FIG. 1. Even in the arrangement in which the gate electrodes have a planar structure, with the n-type barrier layer 20 in only the IGBT cell region A1, the on-state voltage of the IGBT is lowered, and the characteristic degradation of the diode is prevented. Thus, good characteristics of the IGBT and the diode can be attained when they are formed as one chip.

The IGBT or the diode of the semiconductor device of the embodiment may use SiC or GaN instead of silicon.

In the embodiment, even if the p layer and the n layer are totally reversed, similar effects can be obtained.

While certain embodiments have been described, these embodiments have been presented by way of example only, and they are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
transistor cells and diode cells that are formed on a first conductivity type semiconductor substrate;
a first semiconductor layer of a second conductivity type that is formed in a transistor cell region and at a lower side of the semiconductor substrate;
a second semiconductor layer of the first conductivity type that is formed in a region adjacent to the transistor cell region and at the lower side of the semiconductor substrate;
gate electrodes that are formed with a prescribed spacing at an upper side of the semiconductor substrate;
a third semiconductor layer of the second conductivity type that is formed between the gate electrodes;
a fourth semiconductor layer of the first conductivity type that is formed between the gate electrodes;
a fifth semiconductor layer of the first conductivity type that is formed above the first semiconductor layer at the transistor cell region;
a first electrode that is formed on the third semiconductor layer and the fourth semiconductor layer; and
a second electrode that is formed at the lower side of the semiconductor substrate.

2. The semiconductor device according to claim 1, wherein
the fifth semiconductor layer is formed only in the transistor cell region.

3. The semiconductor device according to claim 1, wherein
the second semiconductor layer has a width of 200 μm or smaller.

4. The semiconductor device according to claim 1, wherein
the second semiconductor layer is formed in a grid shape.

5. The semiconductor device according to claim 1, wherein
the second semiconductor layer is arranged in the shape of a water drop.

6. The semiconductor device according to claim 1, wherein
the fourth semiconductor layer is formed on the third semiconductor layer between the gate electrodes.

7. The semiconductor device according to claim 1, wherein
the semiconductor substrate includes SiC or GaN.

8. The semiconductor device according to claim 1, wherein
the fifth semiconductor layer is formed between the semiconductor substrate and the third semiconductor layer.

9. The semiconductor device according to claim 1, wherein
the second semiconductor layer is formed only in the region adjacent to the transistor cell region.

10. A semiconductor device comprising:
transistor cells and diode cells that are formed on a first conductivity type semiconductor substrate;
a first semiconductor layer of a second conductivity type that is formed in an transistor cell region and at a lower side of the semiconductor substrate;
a second semiconductor layer of the first conductivity type that is formed in a region adjacent to the transistor cell region and at the lower side of the semiconductor substrate and that has a width of 200 μm or smaller;
a gate electrode that is formed with a prescribed spacing in an upper side of the semiconductor substrate;
a third semiconductor layer of the second conductivity type that is formed between the gate electrodes;
a fourth semiconductor layer of the first conductivity type that is formed between the gate electrodes;
a first electrode formed on the third semiconductor layer and the fourth semiconductor layer; and
a second electrode formed at the lower side of the semiconductor substrate.

11. The semiconductor device according to claim 10, wherein
the second semiconductor layer is formed in a grid shape.

12. The semiconductor device according to claim 10, wherein
the second semiconductor layer is formed in the shape of a water drop.

13. The semiconductor device according to claim 10, wherein
the fourth semiconductor layer is formed on the third semiconductor layer between the gate electrodes.

14. The semiconductor device according to claim 10, wherein
the semiconductor substrate includes SiC or GaN.

15. The semiconductor device according to claim 10, wherein
the second semiconductor layer is formed only in the region adjacent to the transistor cell region.

16. A method of manufacturing a semiconductor device comprising:
forming trenches with a prescribed spacing on an upper surface of a first conductivity type semiconductor substrate that has a transistor cell region;
forming gate electrodes in the trenches;
forming a first semiconductor layer of a second conductivity type at a lower side of the semiconductor substrate and in the transistor cell region;
forming a second semiconductor layer of first conductivity type at the lower side of the semiconductor substrate and in a region adjacent to the transistor cell region;
forming a third semiconductor layer of the second conductivity type between the gate electrodes;
forming a fourth semiconductor layer of the first conductivity type between the gate electrodes;
forming a fifth semiconductor layer of the first conductivity type above the first semiconductor layer in the transistor cell region;
forming a first electrode on the third semiconductor layer and the fourth semiconductor layer; and
forming a second electrode at the lower side of the semiconductor substrate.

17. The method according to claim 16, wherein
the fifth semiconductor layer is formed only in the transistor cell region.

18. The method according to claim 16, wherein
the second semiconductor layer is formed only in the region adjacent to the transistor cell region.

19. The method according to claim 16, wherein the second semiconductor layer has a width of 200 μm or smaller.

20. The method according to claim 16, wherein the second semiconductor layer is formed in one of a grid shape and a water drop shape.
